(19) United States
(12) Patent Application Publication
(10) Pub. No.: US 2026/0147040 A1
(43) Pub. Date: May 28, 2026

(54) HARDWARE DECODER FOR RUN-LENGTH ENCODED MASK BITS FOR IN-SYSTEM AUTOMATIC TEST PATTERN GENERATION (ATPG)

(71) Applicant: QUALCOMM Incorporated, San Diego, CA (US)

(72) Inventors: Srinivas PATIL, Austin, TX (US); Rajesh Kumar TIWARI, Bangalore (IN); Nir MAOR, San Diego, CA (US)

(21) Appl. No.: 18/956,462

(22) Filed: Nov. 22, 2024

(51) Int. Cl. G01R 31/3183; G01R 31/3185

(52) U.S. Cl. CPC G01R 31/318307; G01R 31/318558

(57) ABSTRACT

A computer implemented decoding method includes decoding a number of run-length encoded mask strings to obtain decoded mask bits for each of a number of scan channels. The method also includes applying the decoded mask bits to automatic test pattern generator (ATPG) scan response data of each scan channel to obtain a multiple input signature register (MISR) signature.

### FIELD OF THE DISCLOSURE

Aspects of the present disclosure generally relate to computing devices, and more particularly to a hardware decoder for run-length encoded mask bits for in-system automatic test pattern generation (ATPG).

### BACKGROUND

Functional safety is an aspect of computer systems design, particularly in automotive, aerospace, industrial automation, and medical device contexts. Functional safety includes implementing mechanisms to increase the likelihood that a system behaves predictably and safely in the presence of faults. Functional safety standards provide frameworks for the development, validation, and verification of safety systems. These standards include rigorous risk assessment, hazard analysis, and the use of redundant and diverse design techniques to mitigate potential hazards. Strategies for implementing functional safety involve built-in self-tests (BISTs), safety integrity levels (SILs), fail-safe and fail-operational modes, and comprehensive safety case documentation to demonstrate that safety specifications are satisfied throughout the product lifecycle.

In the automotive industry, vehicles are rated via an Automotive Safety Integrity Level (ASIL) rating system. ASIL ratings, ranging from ASIL-A to ASIL-D, categorize the severity of potential hazards and the rigor specified to mitigate the hazards. ASIL-A represents the lowest safety integrity level and is awarded to systems implementing fewer safety measures, while ASIL-D signifies the highest safety integrity level and is awarded to systems implementing more stringent safety protocols. These ratings guide automotive development, validation, and verification processes to increase the likelihood that automotive systems can operate safely, even in the presence of faults. The ASIL framework encompasses risk assessment, hazard analysis, and the implementation of redundant and diverse safety mechanisms to prevent or mitigate failures. In-system automatic test pattern generation (ATPG) is one technique for ensuring safety specifications are satisfied.

### SUMMARY

In aspects of the present disclosure, a computer implemented decoding method includes decoding a number of run-length encoded mask strings to obtain decoded mask bits for each scan channel of a number of scan channels. The method also includes applying the decoded mask bits to automatic test pattern generator (ATPG) scan response data of each scan channel to obtain a multiple input signature register (MISR) signature.

Other aspects of the present disclosure are directed to an apparatus. The apparatus has a number of finite state machines, each configured to decode a number of run-length encoded mask strings to obtain decoded mask bits for each of a number of scan channels. The apparatus also has logical AND gates configured to apply the decoded mask bits to automatic test pattern generator (ATPG) scan response data of each scan channel to obtain a multiple input signature register (MISR) signature.

Other aspects of the present disclosure are directed to an apparatus. The apparatus has a memory and one or more processors coupled to the memory. The processor(s) is configured to decode a number of run-length encoded mask strings to obtain decoded mask bits for each scan channel of a number of scan channels. The processor(s) is also configured to apply the decoded mask bits to automatic test pattern generator (ATPG) scan response data of each scan channel to obtain a multiple input signature register (MISR) signature.

Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings in which like reference characters identify correspondingly throughout.

FIG. 1 illustrates an example implementation of a system-on-a-chip (SOC), in accordance with various aspects of the present disclosure.

FIG. 2 illustrates an example of an automobile including systems that may be adapted, configured, or operated, in accordance with various aspects of the present disclosure.

FIG. 3 is a block diagram illustrating an Automotive Safety Integrity Level (ASIL) data path.

FIG. 4 is a logic diagram illustrating masking for cycle-by-cycle bit comparisons, in accordance with various aspects of the present disclosure.

FIG. 5 is a logic diagram illustrating masking for multiple input signature register (MISR) signature generation, in accordance with various aspects of the present disclosure.

FIG. 6 is a diagram illustrating run-length encoding, in accordance with various aspects of the present disclosure.

FIG. 7 is an architectural diagram illustrating a run-length decoder, in accordance with various aspects of the present disclosure.

FIG. 8 is a flow diagram illustrating finite state machine processing, in accordance with various aspects of the present disclosure.

FIG. 9 is a flow chart illustrating an example process performed, for example, by a run-length decoder, in accordance with various aspects of the present disclosure.

FIG. 10 is a block diagram illustrating a design workstation used for circuit, layout, and logic design of run-length decoder components, in accordance with various aspects of the present disclosure.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

Based on the teachings, one skilled in the art should appreciate that the scope of the disclosure is intended to cover any aspect of the disclosure, whether implemented independently of or combined with any other aspect of the disclosure. For example, an apparatus may be implemented or a method may be practiced using any number of the aspects set forth. In addition, the scope of the disclosure is intended to cover such an apparatus or method practiced using other structure, functionality, or structure and functionality in addition to or other than the various aspects of the disclosure set forth. It should be understood that any aspect of the disclosure disclosed may be embodied by one or more elements of a claim.

The word “exemplary” is used to mean “serving as an example, instance, or illustration.” Any aspect described as “exemplary” is not necessarily to be construed as preferred or advantageous over other aspects.

Although particular aspects are described, many variations and permutations of these aspects fall within the scope of the disclosure. Although some benefits and advantages of the preferred aspects are mentioned, the scope of the disclosure is not intended to be limited to particular benefits, uses or objectives. Rather, aspects of the disclosure are intended to be broadly applicable to different technologies, system configurations, networks, and protocols, some of which are illustrated by way of example in the figures and in the following description of the preferred aspects. The detailed description and drawings are merely illustrative of the disclosure rather than limiting, the scope of the disclosure being defined by the appended claims and equivalents thereof.

Several aspects of functional safety management will now be presented with reference to various apparatuses and techniques. These apparatuses and techniques will be described in the following detailed description and illustrated in the accompanying drawings by various blocks, modules, components, circuits, steps, processes, algorithms, and/or the like (collectively referred to as “elements”). These elements may be implemented using hardware, software, or combinations thereof. Whether such elements are implemented as hardware or software depends upon the particular application and design constraints imposed on the overall system.

For automotive designs, in-system tests are needed to comply with international safety standards, such as the international organization for standardization (ISO) 26262. One such in-system test technique is in-system automatic test pattern generation (ATPG), which relies on storing deterministic patterns on-die to apply to the design in the field. In-system ATPG has many advantages, such as lower test time and less design overhead, compared to other methods (such as logic built-in self-test (LBIST)). The low test time is especially attractive for new test paradigms coming on the horizon, such as periodic built-in self-test (BIST), which are needed to achieve higher levels of safety. However, a primary drawback of in-system ATPG is the storage space needed on-die for the patterns. Any technique to reduce the storage requirements can reduce the average unit cost (AUC) of a die. One component of on-die storage for ATPG patterns is mask bits that are used to ignore design responses that are unknown. Aspects of the present disclosure reduce the storage for mask bits to a negligible level and can overall reduce the storage requirement for patterns.

To save storage space, run-length encoded (RLE) mask bits are stored on-die. Mask bits are decoded on-die prior to conducting a response comparison or signature computation. Run-length encoding is a compression technique that relies on using counters for consecutive occurrences of same symbols (runs) and replaces the runs by the symbol and a repeat count. Mask bits are binary strings that contain high occurrences of a binary digit (assume 1 in this case) versus the complimentary value (0s). Hence, Is can be run-length encoded (RLE) to reduce storage. The string of 1s can be replaced by a run-length encoded string. Aspects of the present disclosure introduce hardware decoding/decompressing for on-the-fly run-length decoding/decompressing of RLE mask bits, without the need to store decoded mask bits. The decoding hardware includes mask registers, run-length decoder (RLD) finite state machines (FSMs), valid generation logic, a scan clock counter, a multiple input signature register (MISR), a scan clock gate, and a free running scan clock.

Particular aspects of the subject matter described in this disclosure can be implemented to realize one or more of the following potential advantages. In some examples, the described techniques and components, such as performing hardware run-length decoding/decompressing operations, do not require memory to store uncompressed mask bits, and thus reduce overall mask bit storage. Additional advantages include avoiding a software agent, such as a central processing unit (CPU), for decoding, which is useful in hardware-based in-system tests, for example, to improve testing speed.

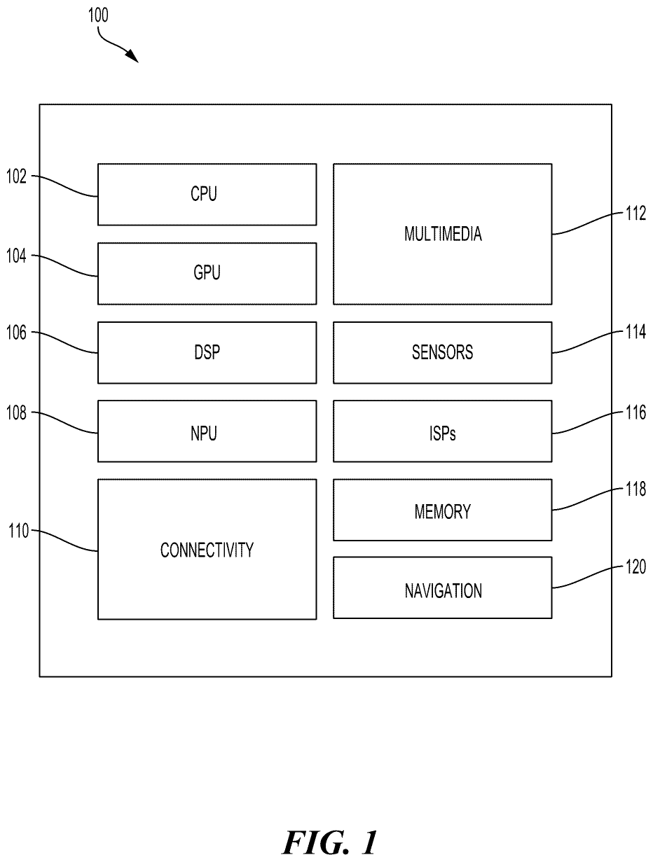

FIG. 1 illustrates an example implementation of a system-on-a-chip (SOC) 100, which may include a central processing unit (CPU) 102 or a multi-core CPU configured for run-length decoding operations. Variables (e.g., neural signals and synaptic weights), system parameters associated with a computational device (e.g., neural network with weights), delays, frequency bin information, and task information may be stored in a memory block associated with a neural processing unit (NPU) 108, in a memory block associated with a CPU 102, in a memory block associated with a graphics processing unit (GPU) 104, in a memory block associated with a digital signal processor (DSP) 106, in a memory block 118, or may be distributed across multiple blocks. Instructions executed at the CPU 102 may be loaded from a program memory associated with the CPU 102 or may be loaded from a memory block 118.

The SOC 100 may also include additional processing blocks tailored to specific functions, such as a GPU 104, a DSP 106, a connectivity block 110, which may include fifth generation (5G) connectivity, fourth generation long term evolution (4G LTE) connectivity, Wi-Fi connectivity, USB connectivity, Bluetooth connectivity, and the like, and a multimedia processor 112 that may, for example, detect and recognize gestures. In one implementation, the NPU 108 is implemented in the CPU 102, DSP 106, and/or GPU 104. The SOC 100 may also include a sensor processor 114, image signal processors (ISPs) 116, and/or navigation module 120, which may include a global positioning system.

The SOC 100 may be based on any architecture, such as a complex instruction set (CISC) architecture, an ARM, RISC-V (RISC-five), or any reduced instruction set computing (RISC) architecture. In aspects of the present disclosure, the instructions loaded into the CPU 102 may include code to decode a number of run-length encoded mask strings to obtain decoded mask bits for each of a number of scan channels. In aspects of the present disclosure, the instructions loaded into the CPU 102 may include code to apply the decoded mask bits to automatic test pattern generator (ATPG) scan response data of each scan channel to obtain a multiple input signature register (MISR) signature.

According to aspects of the present disclosure, an apparatus includes a run-length decoder mechanism. The apparatus may include means for decoding, means for applying, means for loading, means for serially shifting, means for generating, means for asserting, means for counting, and means for repeating. For example, the means for may be any of the CPU 102, GPU 104, DSP 106, NPU 108, memory 118, central controller 220, CPU cluster 302, mask register 702, finite state machine 704, valid generation logic 706, scan clock counter 708, and/or scan clock gate 712.

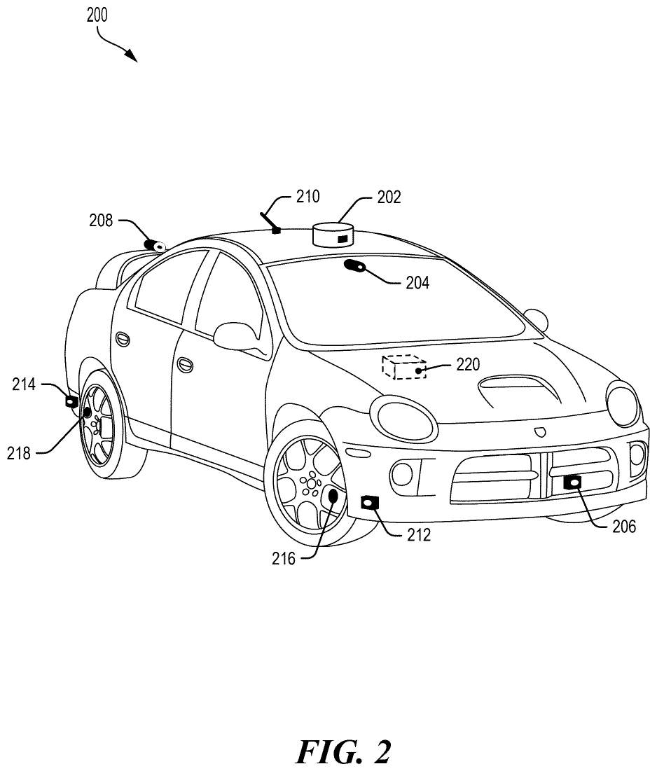

FIG. 2 illustrates an example of an automobile including systems that may be adapted, configured, or operated in accordance with various aspects of this disclosure. The automobile 200 may be equipped with multiple imaging or sensing devices including, for example, cameras 202, 204, 206, 208, 212, 214, and sensors 216, 218. The automobile 200 may include sensors such as tire pressure or braking sensors as the sensors 216, 218. The automobile 200 may also include one or more antennas 210 for radio frequency reception, wireless communication and/or radio navigation using a position location system, such as a global positioning system (GPS). A central controller 220 may be coupled to each of the cameras 202, 204, 206, 208, 212, 214, sensors 216, 218 and antennas 210. The central controller 220 may configure and manage automated systems and/or driver assistance systems. In some implementations, the central controller 220 may be configured to operate as an engine control unit that manages the operation and performance of the engine, motor, motors, or other power systems in the automobile 200. In some instances, the central controller 220 may include an SOC, such as the SOC 100.

Robust data communication links are specified to support the large number of cameras deployed within the automobile 200. In some examples, 20-30 cameras may be deployed to support automation and driver assistance systems. Each camera may be capable of generating data at a rate of between 1-10 gigabits per second (GBps) resulting in aggregate data rates of up to 300 GBps.

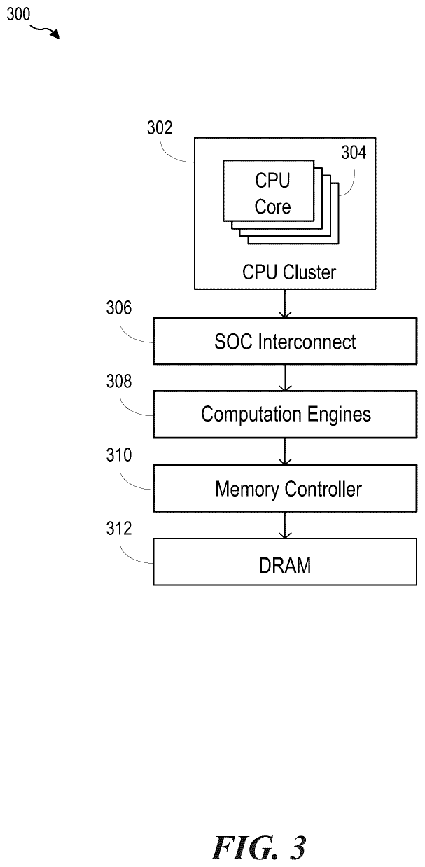

FIG. 3 is a block diagram illustrating an automotive data path 300. As shown, the data path 300 includes a CPU cluster 302. Although a single CPU cluster 302 is depicted for ease of explanation, the present disclosure is not so limited. The CPU cluster 302 includes a set of CPU cores 304 that work concurrently or in parallel to perform computational tasks via workloads distributed across the set of CPU cores 304. The set of CPU cores 304 are respectively interconnected such that each core may perform a portion of a task. Portions of a task may be assigned to each core of the CPU cores 304 by a scheduler (not illustrated) hosted by the CPU cluster 302. The CPU cluster 302 is coupled to an SOC interconnect 306.

The SOC interconnect 306 links various upstream components, such as the CPU cluster 302 and cache (not illustrated) to various downstream components. Additionally, the SOC interconnect 306 facilitates on-chip communications and transaction handling between the upstream components and downstream components on the data path 300. The SOC interconnect 306 is coupled to computation engines 308. The computation engines 308 represent one or more logic structures on the data path 300 that are downstream from the SOC interconnect 306.

The computation engines 308 may include functionally complex, area intensive logic structures on the path to dynamic random access memory (DRAM) in an SOC. For example, the computation engines 308 may include compression engines, encryption engines, a last-level cache, and other computational or memory structures. Compression engines apply compression techniques to reduce the data footprint of data packets transmitted on the data path 300, thus reducing bandwidth specified to transmit the data packets. Encryption engines implement cryptographic techniques to encrypt data packets. A last-level cache serves as high-capacity, low-latency memory storage for upstream components such as the CPU cluster 302. The computation engines 308 are coupled to a memory controller 310.

The memory controller 310 manages data flow between DRAM 312 and upstream components on the data path 300, such as the CPU cluster 302. The memory controller 310 coordinates memory access requests from the upstream components to reduce memory bandwidth and latency. The DRAM 312, coupled to the memory controller 310, serves as the primary volatile storage for the data path 300, providing memory space for stored information. While smaller data packets and data packets specifying low access latency may be stored in a cache within the data path 300, larger data packets and data packets specifying higher access latency may instead by stored in the DRAM 312 by the memory controller 310.

In FIG. 3, each of the components in the data path 300 may be rated as conforming to the highest safety integrity level, e.g., ASIL-D. For instance, ASIL-D may specify strict path protection across complex structures, such as the computation engines 308, memory controller 310, and DRAM 312. Similarly, other safety levels, such as ASIL-C, may also be associated with components in the data path 300. Safety systems, the CPU cluster 302, and other critical systems may be tested upon boot up to ensure compliance with the safety specifications. Each of these components in the data path 300 may be subject to in-system test mechanisms when powering on and powering off the vehicle and while operating the vehicle in the field.

Automotive products incorporate various in-system test mechanisms to ensure safety, such as logic built-in self-test (LBIST) and in-system automatic test pattern generation (ATPG). LBIST targets permanent faults using on-die pseudo-random pattern generators (PRPG) and response compactors, such as multi-input signature registers (MISRs). LBIST relies on the design to be X-free and random pattern testable, which entails significant design overhead and effort. X-free refers to having no ‘don't care’ bits, where an X bit is irrelevant when determining a test result. The Xs are due to unknown values, and hence have to be ignored for response comparison or compression. High fault coverages are difficult to achieve with LBIST, test times are high, and only simple fault models may be targeted.

In-system automatic test pattern generation (ATPG) is a promising technique that offers advantages over LBIST, including being faster than LBIST. In-system ATPG can utilize existing ATPG infrastructure established for manufacturing tests, saving design overhead and effort. A pattern may be derived to target a specific fault. In-system ATPG is X-tolerant, meaning the design does not need to be modified to block X bits. Moreover, in-system ATPG can target complex fault models and can be used for other applications, such as predictive maintenance through health monitoring.

A disadvantage of in-system ATPG is the storage needed for the test patterns. That is, in-system ATPG requires mask bits to accompany the expected responses. Aspects of the present disclosure are directed to an apparatus and a method to decode mask bits that have been compressed or encoded using run-length encoding (RLE).

Mask strings will now be discussed. ATPG scan response data is a string of 1s and 0s with a few ‘X’s (e.g., don't care bits). The Xs are due to unknown values, and are ignored for response comparison or compression. Mask bits denote positions of Xs so that automatic test equipment (ATE) can ignore values in those positions. The mask bits block X bits during comparison via a comparator or during signature creation by an MISR. Typically, a ‘1’ (or ‘0’) mask bit in a bit position means the response bit in the corresponding position is to be compared or compressed, and a ‘0’ (or ‘1’) means the response bit is to be ignored (e.g., masked). The ‘1’s usually outnumber ‘0’s because don't care bits are relatively sparse in a mostly X-clean design.

Masks may be used for cycle-by-cycle comparison, or to block X bits input into a MISR.

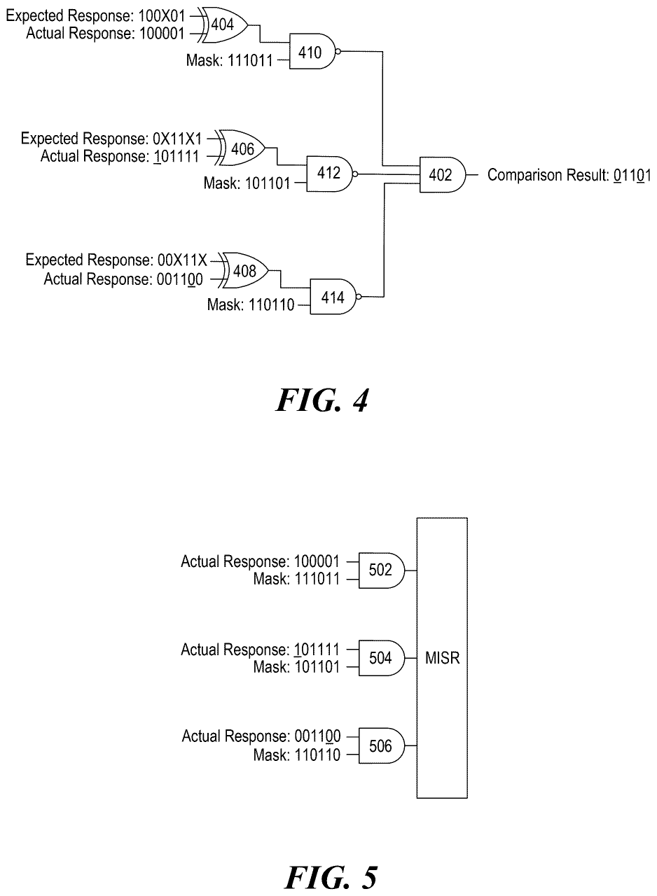

FIG. 4 is a logic diagram illustrating masking for cycle-by-cycle bit comparisons, in accordance with various aspects of the present disclosure. In the example of FIG. 4, an output of a comparator 402 is expected to be Is on all cycles for a passing device. A 0 output on any cycle indicates a failure detected on that cycle. For example, a first logical exclusive OR (XOR) gate 404 receives an expected response that matches an actual response. In contrast, second and third XOR gates 406, 408 receive actual responses that differ from the expected responses in the first and fifth bits (shown underlined), respectively.

The expected response input to the first XOR gate 404 includes an X bit in the fourth position, the expected response input to the second first XOR gate 406 includes X bits in the second and fifth positions, and the expected response input to the third XOR gate 408 includes X bits in the third and sixth positions. Accordingly, mask strings are generated with 0s corresponding to the X bits for each expected response. A mask bit allows any difference between an expected response and an actual response in a corresponding bit position to pass through to the comparator 402. The mask bits may be received at logical negative AND (NAND) gates 410, 412, 414 to mask out bits in the X positions.

FIG. 5 is a logic diagram illustrating masking for multiple input signature register (MISR) signature generation, in accordance with various aspects of the present disclosure. In the case of a MISR, an X-free signature is compared with an expected signature at the end of a test. Logical AND gates 502, 504, 506 receive the actual response along with a mask string, outputting the X-free signature into a MISR.

Run-length encoding is a compression technique. Because mask data can contain long continuous strings of 1s, also known as a run, mask data is amenable to run-length encoding (RLE). Run-length encoding can reduce an amount of storage needed for mask data. A run, or a continuous repetition, of a particular symbol can be replaced by the symbol followed by a count, providing log₂(N) compression. Because mask bits are more likely to contain longer runs of Is rather than 0s, the string of Is can be replaced by a run-length encoded string. The same can be done for 0s, but with less benefit. If the run of 0s is short, the encoding may cost additional storage.

A counter field may be determined from a distribution of 0s amongst 1s. Assuming a uniform distribution of 0s, the RLE counter

$$length = ⌈ {log}_{2} \frac{( Total length of mask string )}{( A v g 0 s + 1 )} ⌉ .$$

If a run of Is exceeds the count that can be stored in a fixed width counter, the remaining Is are encoded using one or more additional fixed-width counter fields.

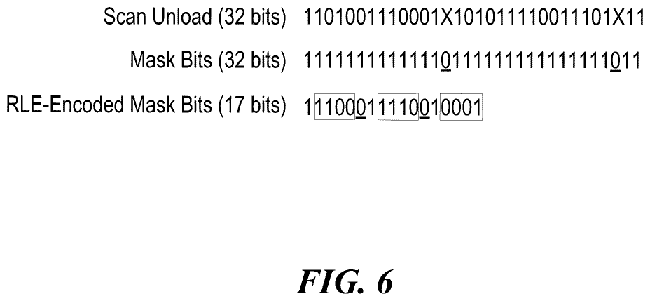

FIG. 6 is a diagram illustrating run-length encoding (RLE), in accordance with various aspects of the present disclosure. In the example of FIG. 6, the counter width=4. The scan unload data is 32 bits, with two X bits. The resulting mask bits include 0s at the corresponding bit positions. After RLE, only 17 mask bits are needed, resulting in an almost 50% savings in storage space. In the example of FIG. 6, the first position in the encoded mask bits is a 1, indicating a string of 1s follows. The string of Is includes 12 (e.g., binary 1100) Is. Next, a 0 occurs in the encoded mask bits, followed by a 1 and a string of 14 (e.g., binary 1110) 1s. Finally, another 0 appears followed by a 1 and one (e.g., binary 0001) additional 1.

To save storage, RLE mask bits are stored on-die. Mask bits are decoded on-die prior to a response comparison or signature computation. Software-based decoding can be used, but software decoding has disadvantages. For example, a central processing unit (CPU) may not be available during the test process. Moreover, temporary storage is required for decoded mask bits, which negates some of the benefits of RLE. Furthermore, software may impose additional test time overhead.

Aspects of the present disclosure introduce hardware decoding for on-the-fly run-length decoding without the need to store decoded mask bits.

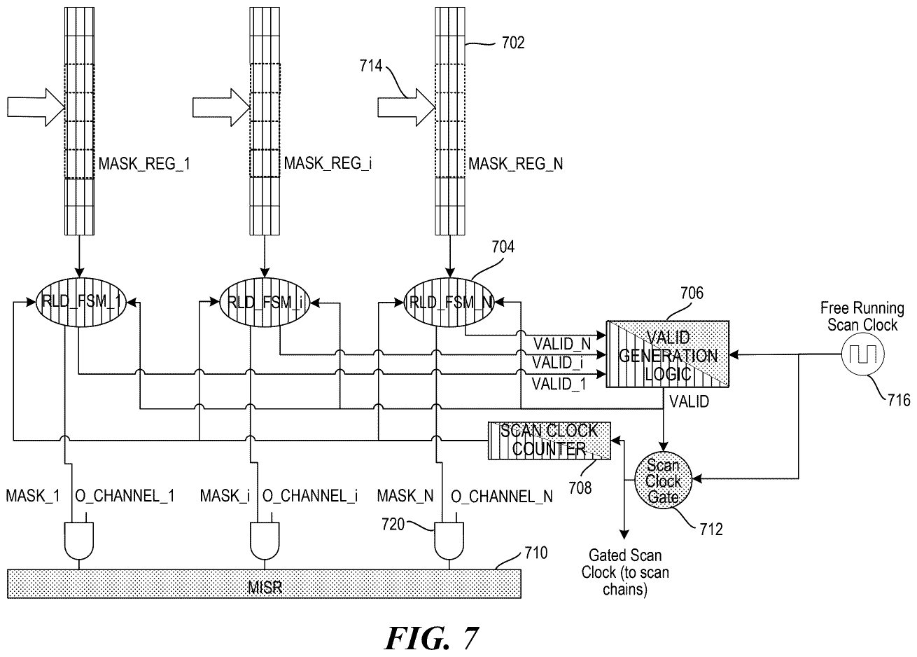

FIG. 7 is an architectural diagram illustrating a run-length decoder, in accordance with various aspects of the present disclosure. In the example of FIG. 7, there are two primary clock domains. A first clock domain includes mask registers 702 (only one mask register labelled), run-length decoder (RLD) finite state machines (FSMs) 704 (only one FSM labelled), valid generation logic 706, and a scan clock counter 708. The first clock domain may be faster than a second clock domain. The first clock domain is for operating the RLD finite state machines 704. The second clock domain is for scan shift and includes a MISR 710, a scan clock gate 712, the valid generation logic 706, and the scan clock counter 708. The architecture of the present disclosure allows the two clock domains to be either asynchronous or synchronous. Potential clock crossings in the valid generation logic 706 and the scan clock counter 708 are shown in shaded blocks. Proper clock crossing logic (such as meta-stable flip-flops) is included for robust data transfer in these blocks 706, 708.

For N scan channels, N mask registers (MASK_REG_1 through MASK_REG_N) 702 are needed. The size of the registers can be aligned with a size of system/network-on-chip (NOC) registers. That is, the mask registers need not be as long as the mask chains. RLE mask bits can be transferred in chunks into the mask registers 702 as the mask bits are applied to scan channel outputs (O_CHANNEL_1 through O_CHANNEL_N). The mask registers 702 are loaded via a parallel bus 714 (only one bus is labelled) and can be software or hardware-programmable registers. The bits in the mask registers 702 are consumed (e.g., shifted out) serially by the RLD FSM 704 (RLD_FSM_i through RLD_FSM_N).

The outputs of the RLD FSM 704 include individual valid bits (VALID_i through VALID_N) and mask bits (MASK_i through MASK_N). The individual valid bit (VALID_i) indicates when a mask bit is valid and is needed due to the variable length of mask bits. That is, mask bits for all channels for a particular shift cycle may not be valid at the same time. For example, as seen in FIG. 6, the binary value of 1 includes three leading zeros and thus has a length of only 1, whereas the binary value of 14 has three Is and a length of three. The mask bit (MASK_i) is a valid encoded mask bit when the valid bit (VALID_i) is high.

Because the individual valid bits (VALID_i through VALID_N) are present at different times, the system stalls until all valid bits (VALID_i through VALID_N) arrive. Thus, the valid generation logic 706 generates a composite valid signal (VALID (with no subscript)) that is high when all valid bits received from all of the RLD FSMs 704 are high. In some implementations, the composite valid bit (VALID) is high for a duration of exactly one shift cycle, and de-asserted after every valid mask bit. The composite valid signal (VALID) enables exactly one shift clock pulse so that one bit from each scan chain (e.g., scan channel outputs (O_CHANNEL_i)) can be logically ANDed with corresponding mask bits (MASK_i) at an AND gate 720 and compressed into a MISR signature for storage at a MISR 710. Based on the run-length, the logic can be further improved so the composite valid signal (VALID) is high for the entire duration of 1s, instead of de-asserting the composite valid signal (VALID) after every valid mask bit.

The scan clock counter 708 resets the RLD FSMs 704 to a START state once all scan channels (O_CHANNEL_1 through O_CHANNEL_N) are fully loaded. That is, the scan clock counter 708 counts down the total number of bits, starting at the scan chain length. Once the countdown reaches zero, the RLD FSMs 704 reset. The scan clock gate 712 enables the scan clock 716 for one full cycle.

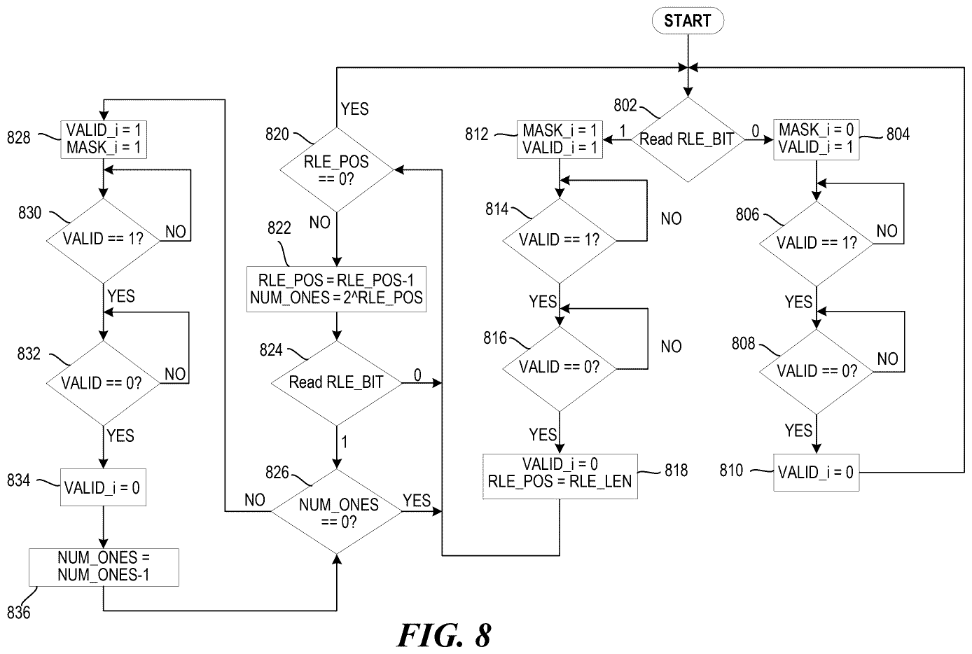

FIG. 8 is a flow diagram illustrating finite state machine processing, in accordance with various aspects of the present disclosure. The run-length decoder FSM (RLD_FSM) 704 initially reads a run-length encoded (RLE) bit from a mask register 702 at block 802. If the RLE bit is a 0, at block 804, the RLD FSM 704 sets the mask bit (MASK_i) to 0 and the valid bit (VALID_i) to 1. At block 806, the logic waits for all valid bits for all scan channels to be 1 before continuing. The wait ensures that all scan channels have valid data. When the composite valid signal (VALID) is 0, the process remains at block 806. When the composite valid signal (VALID) is 1, a valid bit will be consumed for one scan clock duration, in other words, all scan channels are ready. Thus, the logic flows to block 808 where the logic waits for the composite valid signal to be 0. That is, once a bit is consumed by the downstream logic (e.g., when a bit arrives and is shifted out after one scan cycle), the valid generation logic 706 sets the composite valid signal to 0. The valid bit (VALID_i) is then set to 0 at block 810, and the logic returns to block 802.

If, at block 802, the RLE bit is a 1, at block 812, the RLD FSM 704 sets the mask bit (MASK_i) to 1 and the valid bit (VALID_i) to 1. At block 814, the logic loops until all valid bits for all scan channels are 1 (e.g., the composite valid signal is 1). When the composite valid signal (VALID) is 1, all scan channels are ready. Thus, the logic flows to block 816, where the logic loops and waits for the composite valid signal (VALID) to be 0 (e.g., for one scan clock cycle to complete). When the valid generation logic 706 sets the composite valid signal to 0, the valid bit (VALID_i) is then set to 0 at block 818, and the RLE bit position (RLE_POS) is set to the RLE sequence length (RLE_LEN). At block 820, the logic determines whether the RLE bit position is 0. In other words, the logic checks whether all scan chain bits are processed. If so, the logic returns to block 802.

If all scan bits are not processed (820: NO), at block 822, the logic subtracts one from the RLE bit position and sets the number of ones in the mask string (NUM_ONES) to two to the power of the RLE bit position. For example, if the RLE bit position is 2, then the number of ones is set to 4 (i.e., 2\hat{ }2). At block 824, the FSM 704 reads the next RLE bit. If the next RLE bit is a 0, the process returns to block 820. If the next RLE bit is a 1, the process continues to block 826.

At block 826, the logic determines if the value of the number of ones is 0. If so, the logic returns to block 820. If not, the logic continues at block 828, where the FSM 704 sets the mask bit (MASK_i) to 1 and the valid bit (VALID_i) to 1. At block 830, the logic loops until all valid bits for all scan channels are 1 (e.g., the composite valid signal (VALID) is 1). When the composite valid signal is 1, the logic flows to block 832, where the logic loops and waits for the composite valid signal (VALID) to be 0 (e.g., for one scan clock cycle to complete). When the valid generation logic 706 sets the composite valid signal to 0, the valid bit (VALID_i) is then set to 0 at block 834, and the logic continues to block 836. At block 836, the logic subtracts one from the number of ones and the process returns to block 826. In this manner, the mask bits are decoded with on-die hardware, prior to a response comparison or signature computation.

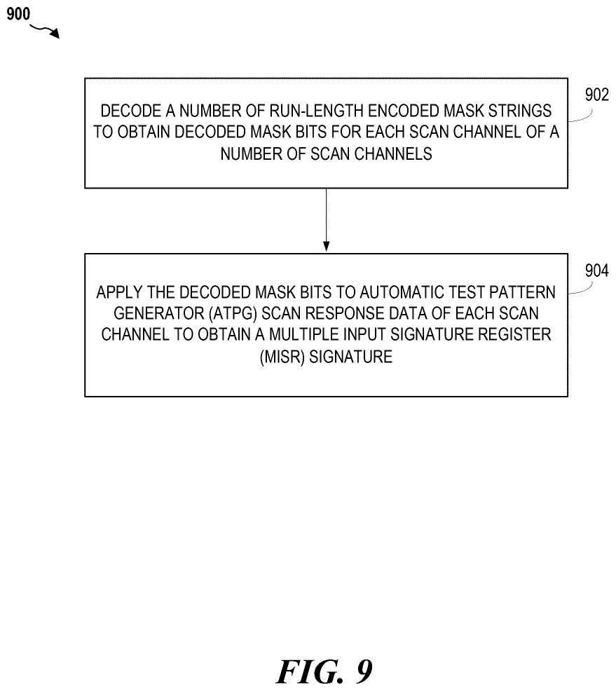

FIG. 9 is a flow chart illustrating an example process 900 performed, for example, by a run-length decoder, in accordance with various aspects of the present disclosure. In some aspects, the process 900 may include decoding a number of run-length encoded mask strings to obtain decoded mask bits for each scan channel of a number of scan channels (block 902). For example, the decoding may generate an individual valid signal for each of the scan channels in response to receiving a valid bit from a corresponding run-length encoded mask string.

In some aspects, the process 900 may include applying the decoded mask bits to automatic test pattern generator (ATPG) scan response data of each scan channel to obtain a multiple input signature register (MISR) signature (block 904). In some aspects, the process counts a quantity of bits shifted out from each scan channel, and repeats the decoding and applying with new run-length encoded mask strings in response to the quantity of bits indicating all scan channels are fully loaded.

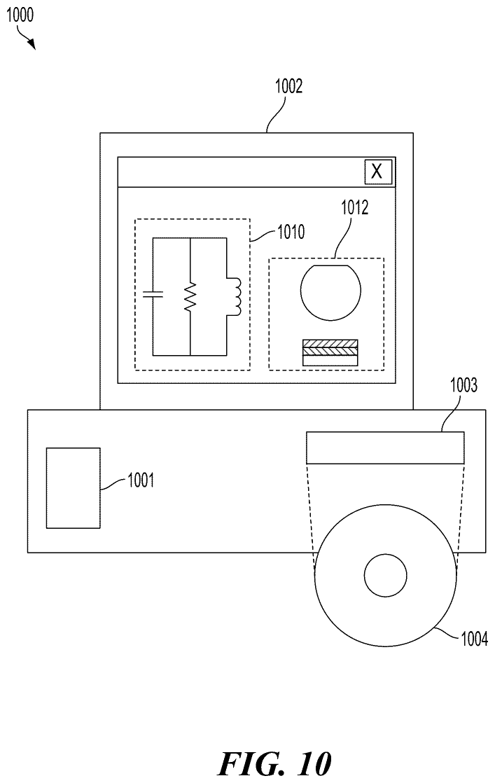

FIG. 10 is a block diagram illustrating a design workstation 1000 used for circuit, layout, and logic design of a semiconductor component, such as the run-length decoder device, disclosed above. The design workstation 1000 includes a hard disk 1001 containing operating system software, support files, and design software such as Cadence or OrCAD. The design workstation 1000 also includes a display 1002 to facilitate design of a circuit 1010 or a semiconductor component 1012, such as the run-length decoder device. A storage medium 1004 is provided for tangibly storing the design of the circuit 1010 or the semiconductor component 1012 (e.g., the run-length decoder device). The design of the circuit 1010 or the semiconductor component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the semiconductor component 1012 by decreasing the number of processes for designing semiconductor wafers.

### EXAMPLE ASPECTS

Aspect 1: A computer implemented decoding method, comprising: decoding a plurality of run-length encoded mask strings to obtain decoded mask bits for each scan channel of a plurality of scan channels; and applying the decoded mask bits to automatic test pattern generator (ATPG) scan response data of each scan channel to obtain a multiple input signature register (MISR) signature.

Aspect 2: The method of Aspect 1, further comprising: loading the plurality of run-length encoded mask strings in parallel to a plurality of mask registers; and serially shifting out bits from each of the mask registers, prior to the decoding.

Aspect 3: The method of Aspect 1 or 2, in which a size of each mask register is smaller than a length of the plurality of run-length encoded mask strings.

Aspect 4: The method of any of the preceding Aspects, in which the decoding further comprises generating an individual valid signal for each of the plurality of scan channels in response to receiving a valid bit from a corresponding run-length encoded mask string.

Aspect 5: The method of any of the preceding Aspects, further comprising asserting a composite valid signal for one scan block cycle in response to receiving individual valid signals corresponding to each of the plurality of scan channels, the asserting of the composite valid signal triggering the applying of the decoded mask bits.

Aspect 6: The method of any of the Aspects 1-4, further comprising asserting a composite valid signal for an entire duration of ones in response to receiving valid signals corresponding to each of the plurality of scan channels, the asserting of the composite valid signal triggering the applying of the decoded mask bits.

Aspect 7: The method of any of the preceding Aspects, further comprising: counting a quantity of bits shifted out from each scan channel; and repeating the decoding and applying with a new plurality of run-length encoded mask strings in response to the quantity of bits indicating all scan channels are fully loaded.

Aspect 8: A decoding apparatus, comprising: a plurality of finite state machines, each configured to decode a plurality of run-length encoded mask strings to obtain decoded mask bits for each scan channel of a plurality of scan channels; and a plurality of logical AND gates configured to apply the decoded mask bits to automatic test pattern generator (ATPG) scan response data of each scan channel to obtain a multiple input signature register (MISR) signature.

Aspect 9: The apparatus of Aspect 8, further comprising a plurality of mask registers configured to receive the plurality of run-length encoded mask strings in parallel, and configured to serially shift out bits from each of the mask registers, for decoding.

Aspect 10: The apparatus of Aspect 8-9, in which a size of each mask register is smaller than a length of the plurality of run-length encoded mask strings.

Aspect 11: The apparatus of any of the Aspects 8-10, in which each finite state machine is further configured to generate a valid signal for each of the plurality of scan channels in response to receiving a valid bit from a corresponding run-length encoded mask string.

Aspect 12: The apparatus of any of the Aspects 8-11, further comprising valid generation logic configured to assert a composite valid signal for one scan block cycle in response to receiving valid signals from each of the finite state machines corresponding to each of the plurality of scan channels, the asserting of the composite valid signal triggering the plurality of logical AND gates to apply the decoded mask bits.

Aspect 13: The apparatus of any of the Aspects 8-11, further comprising valid generation logic configured to assert a composite valid signal for an entire duration of ones in response to receiving valid signals from each of the finite state machines corresponding to each of the plurality of scan channels, the asserting of the composite valid signal triggering the plurality of logical AND gates to apply the decoded mask bits.

Aspect 14: The apparatus of any of the Aspects 8-13, further comprising a scan clock counter configured to count a quantity of bits shifted out from each scan channel, and to trigger the plurality of finite state machines to repeat decoding with a new plurality of run-length encoded mask strings in response to the quantity of bits indicating all scan channels are fully loaded.

Aspect 15: An apparatus, comprising: at least one memory; and at least one processor coupled to the at least one memory, the at least one processor configured: to decode a plurality of run-length encoded mask strings to obtain decoded mask bits for each scan channel of a plurality of scan channels; and to apply the decoded mask bits to automatic test pattern generator (ATPG) scan response data of each scan channel to obtain a multiple input signature register (MISR) signature.

Aspect 16: The apparatus of Aspect 15, in which the at least one processor is further configured: to load the plurality of run-length encoded mask strings in parallel to a plurality of mask registers; and to serially shift out bits from each of the mask registers, prior to the decoding.

Aspect 17: The apparatus of Aspect 15-16, in which a size of each mask register is smaller than a length of the plurality of run-length encoded mask strings.

Aspect 18: The apparatus of any of the Aspects 15-17, in which the at least one processor is further configured to generate an individual valid signal for each of the plurality of scan channels in response to receiving a valid bit from a corresponding run-length encoded mask string.

Aspect 19: The apparatus of any of the Aspects 15-18, in which the at least one processor is further configured to assert a composite valid signal for one scan block cycle in response to receiving individual valid signals corresponding to each of the plurality of scan channels, the asserting of the composite valid signal triggering the applying of the decoded mask bits.

Aspect 20: The apparatus of any of the Aspects 15-18, in which the at least one processor is further configured to assert a composite valid signal for an entire duration of ones in response to receiving valid signals corresponding to each of the plurality of scan channels, the asserting of the composite valid signal triggering the applying of the decoded mask bits.

The various operations of methods described above may be performed by any suitable means capable of performing the corresponding functions. The means may include various hardware and/or software component(s) and/or module(s), including, but not limited to, a circuit, an application specific integrated circuit (ASIC), or processor. Generally, where there are operations illustrated in the figures, those operations may have corresponding counterpart means-plus-function components with similar numbering.

As used, the term “determining” encompasses a wide variety of actions. For example, “determining” may include calculating, computing, processing, deriving, investigating, looking up (e.g., looking up in a table, a database, or another data structure), ascertaining and the like. Additionally, “determining” may include receiving (e.g., receiving information), accessing (e.g., accessing data in a memory) and the like. Furthermore, “determining” may include resolving, selecting, choosing, establishing, and the like.

As used, a phrase referring to “at least one of” a list of items refers to any combination of those items, including single members. As an example, “at least one of: a, b, or c” is intended to cover: a, b, c, a-b, a-c, b-c, and a-b-c.

The various illustrative logical blocks, modules and circuits described in connection with the present disclosure may be implemented or performed with a general-purpose processor, a digital signal processor (DSP), an application specific integrated circuit (ASIC), a field programmable gate array signal (FPGA) or other programmable logic device (PLD), discrete gate or transistor logic, discrete hardware components or any combination thereof designed to perform the functions described. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in any form of storage medium that is known in the art. Some examples of storage media that may be used include random access memory (RAM), read-only memory (ROM), flash memory, erasable programmable read-only memory (EPROM), electrically erasable programmable read-only memory (EEPROM), registers, a hard disk, a removable disk, a CD-ROM and so forth. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a device. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement signal processing functions. For certain aspects, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processor may be responsible for managing the bus and general processing, including the execution of software stored on the machine-readable media. The processor may be implemented with one or more general-purpose and/or special-purpose processors. Examples include microprocessors, microcontrollers, DSP processors, and other circuitry that can execute software. Software shall be construed broadly to mean instructions, data, or any combination thereof, whether referred to as software, firmware, middleware, microcode, hardware description language, or otherwise. Machine-readable media may include, by way of example, random access memory (RAM), flash memory, read-only memory (ROM), programmable read-only memory (PROM), erasable programmable read-only memory (EPROM), electrically erasable programmable Read-only memory (EEPROM), registers, magnetic disks, optical disks, hard drives, or any other suitable storage medium, or any combination thereof. The machine-readable media may be embodied in a computer-program product. The computer-program product may comprise packaging materials.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the device, all which may be accessed by the processor through the bus interface. Alternatively, or in addition, the machine-readable media, or any portion thereof, may be integrated into the processor, such as the case may be with cache and/or general register files. Although the various components discussed may be described as having a specific location, such as a local component, they may also be configured in various ways, such as certain components being configured as part of a distributed computing system.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may comprise one or more neuromorphic processors for implementing the neuron models and models of neural systems described. As another alternative, the processing system may be implemented with an application specific integrated circuit (ASIC) with the processor, the bus interface, the user interface, supporting circuitry, and at least a portion of the machine-readable media integrated into a single chip, or with one or more field programmable gate arrays (FPGAs), programmable logic devices (PLDs), controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

The machine-readable media may comprise a number of software modules. The software modules include instructions that, when executed by the processor, cause the processing system to perform various functions. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a general register file for execution by the processor. When referring to the functionality of a software module below, it will be understood that such functionality is implemented by the processor when executing instructions from that software module. Furthermore, it should be appreciated that aspects of the present disclosure result in improvements to the functioning of the processor, computer, machine, or other system implementing such aspects.

If implemented in software, the functions may be stored or transmitted over as one or more instructions or code on a computer-readable medium. Computer-readable media include both computer storage media and communication media including any medium that facilitates transfer of a computer program from one place to another. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Additionally, any connection is properly termed a computer-readable medium. For example, if the software is transmitted from a website, server, or other remote source using a coaxial cable, fiber optic cable, twisted pair, digital subscriber line (DSL), or wireless technologies such as infrared (IR), radio, and microwave, then the coaxial cable, fiber optic cable, twisted pair, DSL, or wireless technologies such as infrared, radio, and microwave are included in the definition of medium. Disk and disc, as used, include compact disc (CD), laser disc, optical disc, digital versatile disc (DVD), floppy disk, and Blu-ray® disc where disks usually reproduce data magnetically, while discs reproduce data optically with lasers. Thus, in some aspects, computer-readable media may comprise non-transitory computer-readable media (e.g., tangible media). In addition, for other aspects computer-readable media may comprise transitory computer-readable media (e.g., a signal). Combinations of the above should also be included within the scope of computer-readable media.

Thus, certain aspects may comprise a computer program product for performing the operations presented. For example, such a computer program product may comprise a computer-readable medium having instructions stored (and/or encoded) thereon, the instructions being executable by one or more processors to perform the operations described. For certain aspects, the computer program product may include packaging material.

Further, it should be appreciated that modules and/or other appropriate means for performing the methods and techniques described can be downloaded and/or otherwise obtained by a user terminal and/or base station as applicable. For example, such a device can be coupled to a server to facilitate the transfer of means for performing the methods described. Alternatively, various methods described can be provided via storage means (e.g., RAM, ROM, a physical storage medium such as a compact disc (CD) or floppy disk, etc.), such that a user terminal and/or base station can obtain the various methods upon coupling or providing the storage means to the device. Moreover, any other suitable technique for providing the methods and techniques described to a device can be utilized.

It is to be understood that the claims are not limited to the precise configuration and components illustrated above. Various modifications, changes, and variations may be made in the arrangement, operation, and details of the methods and apparatus described above without departing from the scope of the claims.

The invention claimed is:

1. A computer implemented decoding method, comprising:
decoding a plurality of run-length encoded mask strings to obtain decoded mask bits for each scan channel of a plurality of scan channels; and
applying the decoded mask bits to automatic test pattern generator (ATPG) scan response data of each scan channel to obtain a multiple input signature register (MISR) signature.

2. The method of claim 1, further comprising:
loading the plurality of run-length encoded mask strings in parallel to a plurality of mask registers; and
serially shifting out bits from each of the mask registers, prior to the decoding.

3. The method of claim 2, in which a size of each mask register is smaller than a length of the plurality of run-length encoded mask strings.

4. The method of claim 1, in which the decoding further comprises generating an individual valid signal for each of the plurality of scan channels in response to receiving a valid bit from a corresponding run-length encoded mask string.

5. The method of claim 4, further comprising asserting a composite valid signal for one scan block cycle in response to receiving individual valid signals corresponding to each of the plurality of scan channels, the asserting of the composite valid signal triggering the applying of the decoded mask bits.

6. The method of claim 4, further comprising asserting a composite valid signal for an entire duration of ones in response to receiving valid signals corresponding to each of the plurality of scan channels, the asserting of the composite valid signal triggering the applying of the decoded mask bits.

7. The method of claim 1, further comprising:
counting a quantity of bits shifted out from each scan channel; and
repeating the decoding and applying with a new plurality of run-length encoded mask strings in response to the quantity of bits indicating all scan channels are fully loaded.

8. A decoding apparatus, comprising:
a plurality of finite state machines, each configured to decode a plurality of run-length encoded mask strings to obtain decoded mask bits for each scan channel of a plurality of scan channels; and
a plurality of logical AND gates configured to apply the decoded mask bits to automatic test pattern generator (ATPG) scan response data of each scan channel to obtain a multiple input signature register (MISR) signature.

9. The apparatus of claim 8, further comprising a plurality of mask registers configured to receive the plurality of run-length encoded mask strings in parallel, and configured to serially shift out bits from each of the mask registers, for decoding.

10. The apparatus of claim 9, in which a size of each mask register is smaller than a length of the plurality of run-length encoded mask strings.

11. The apparatus of claim 8, in which each finite state machine is further configured to generate a valid signal for each of the plurality of scan channels in response to receiving a valid bit from a corresponding run-length encoded mask string.

12. The apparatus of claim 11, further comprising valid generation logic configured to assert a composite valid signal for one scan block cycle in response to receiving valid signals from each of the finite state machines corresponding to each of the plurality of scan channels, the asserting of the composite valid signal triggering the plurality of logical AND gates to apply the decoded mask bits.

13. The apparatus of claim 11, further comprising valid generation logic configured to assert a composite valid signal for an entire duration of ones in response to receiving valid signals from each of the finite state machines corresponding to each of the plurality of scan channels, the asserting of the composite valid signal triggering the plurality of logical AND gates to apply the decoded mask bits.

14. The apparatus of claim 8, further comprising a scan clock counter configured to count a quantity of bits shifted out from each scan channel, and to trigger the plurality of finite state machines to repeat decoding with a new plurality of run-length encoded mask strings in response to the quantity of bits indicating all scan channels are fully loaded.

15. An apparatus, comprising:
at least one memory; and
at least one processor coupled to the at least one memory, the at least one processor configured:
to decode a plurality of run-length encoded mask strings to obtain decoded mask bits for each scan channel of a plurality of scan channels; and
to apply the decoded mask bits to automatic test pattern generator (ATPG) scan response data of each scan channel to obtain a multiple input signature register (MISR) signature.

16. The apparatus of claim 15, in which the at least one processor is further configured:
to load the plurality of run-length encoded mask strings in parallel to a plurality of mask registers; and
to serially shift out bits from each of the mask registers, prior to the decoding.

17. The apparatus of claim 16, in which a size of each mask register is smaller than a length of the plurality of run-length encoded mask strings.

18. The apparatus of claim 15, in which the at least one processor is further configured to generate an individual valid signal for each of the plurality of scan channels in response to receiving a valid bit from a corresponding run-length encoded mask string.

19. The apparatus of claim 18, in which the at least one processor is further configured to assert a composite valid signal for one scan block cycle in response to receiving individual valid signals corresponding to each of the plurality of scan channels, the asserting of the composite valid signal triggering the applying of the decoded mask bits.

20. The apparatus of claim 18, in which the at least one processor is further configured to assert a composite valid signal for an entire duration of ones in response to receiving valid signals corresponding to each of the plurality of scan channels, the asserting of the composite valid signal triggering the applying of the decoded mask bits.
